(19) United States
(12) Patent Application Publication
(10) Pub. No.: US 2003/0193077 A1
(43) Pub. Date: Oct. 16, 2003

(54) Bipolar transistor and method of fabricating the same

(75) Inventor: Hiroki Fujii, Kanagawa (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/411,132

(22) Filed: Apr. 11, 2003

(30) Foreign Application Priority Data
Apr. 12, 2002 (JP) 2002-109907

(51) Int. Cl. H01L 31/075

(52) U.S. Cl. 257/656

(57) ABSTRACT

A device isolation region surrounds first and second device regions of a semiconductor substrate and a patterned deep-trench isolation region is embedded through the device isolation region into the substrate. First and second bipolar transistors are respectively formed in the device regions. Each transistor has a collector region and a base region in the substrate, and an emitter embedded in an insulation layer above the base region. Space savings, low collector resistance and low collector-substrate capacitance are achieved by embedding a collector trench contact into boundary portions of the deep-trench and device isolation regions deeper into the substrate to establish an electrical contact with the corrector region. With a single photoetching process, the insulation layer is etched to create openings for the collector trenches simultaneously with openings for the emitters and base regions. Similar structure of the collector trench contact is used advantageously for double-polysilicon self-aligned bipolar transistors.

### BACKGROUND OF THE INVENTION

1. Field of the Invention

The present invention relates generally to semiconductor devices, and more specifically to bipolar transistors and a method of fabricating high-frequency bipolar transistors,

2. Description of the Related Art

Bipolar transistors and BiCMOS devices, preeminent for their high frequency performance, are currently receiving attention due to potential application to a wide range of high-speed analog circuits. In order to meet high frequency demands, it is necessary to increase their maximum frequency. The well known formula indicates that the maximum frequency of a bipolar transistor is inversely variable as a function of its base resistance and collector-base capacitance. Experiments and computer simulations further indicate that collector-substrate capacitance C_{sub} and collector resistance R_{c} are also limiting factors of the maximum frequency. To reduce the collector-substrate capacitance C_{sub} of bipolar transistors integrated on a semiconductor chip, the current practice is to enclose each device with a deep isolation trench that extends through the device separation layer. A similar method is used to reduce the collector resistance R_{c} by forming a tungsten-embedded trench around a collector contact. However, these trenches additionally require two photoetching processes, Because of their tedious and time consuming processes, the provision of a deep isolation trench and a collector trench adds an extra cost to the manufacture of bipolar transistors.

Japanese Patent Publication 1995-142498 discloses a fabrication process that creates the collector trenches without using the photoetching process. According to this technique, a nitride layer of a semiconductor wafer is patterned to form a plurality of emitter windows where polysilicon emitter electrodes will be fabricated and a plurality of collector openings are patterned. An etching process is further performed on the collector openings to produce collector trenches. However, this prior art requires that collector contacts be formed on a diffused region. As a result, a substantial amount of space must be reserved not only for the individual devices, but also for their isolation from adjacent devices.

This is particularly disadvantageous for bipolar transistors of double-polysilicon self-aligned structure where collector openings must be coated with oxide/nitride sidewalls. The collector openings must be of sufficient size to accommodate these sidewalls. Hence, the prior art bipolar transistor of this type is unsatisfactory to increase packing density. On the other hand, the maximum frequency of this type of transistor could be increased by reducing its base resistance by coating the polysilicon base with a silicide layer. This could be done during an emitter patterning process in which laminated layers of nitride and polysilicon are etched. However, possibility exists that the sidewalls of the collector openings would fall apart and contaminate the patterning process when the process is continued to etch the underlying nitride layer.

### SUMMARY OF THE INVENTION

It is therefore an object of the present invention to provide a bipolar transistor having narrow device separation, low collector resistance R_{c} and low collector-substrate capacitance C_{sub}.

It is another object of the present invention to provide a method of fabricating bipolar transistors wherein narrow device separation, low collector resistance R_{c} and low collector-substrate capacitance C_{sub} are simultaneously achieved by the use of only one photoetching process.

A further object of the present invention is to provide a method of providing narrow device separation, low collector resistance R_{c} and low collector-substrate capacitance C_{sub} for double-polysilicon self-aligned bipolar transistors by using only one photoetching process.

According to a first aspect of the present invention, there is provided a bipolar transistor which comprises a patterned deep-trench isolation region formed in a device isolation region which surrounds a device region of a semiconductor body, the deep-trench isolation region being embedded into the semiconductor body deeper than the device isolation region, a base formed in the device region, an emitter situated on the base, and a collector. The collector comprises a collector region which forms a collector-base junction with the base and a collector trench contact embedded into boundary portions of the deep-trench isolation region and the device isolation region deeper than the device isolation region to establish an electrical contact with the corrector region.

In a double-polysilicon self-aligned bipolar transistor, the base and the emitter are respectively composed of a lower polysilicon layer and an upper polysilicon layer situated on the lower polysilicon layer.

According to a second aspect of the present invention, there is provided a method of fabricating a bipolar transistor. The method comprises forming a patterned deep-trench isolation region in a device isolation region which surrounds a device region of a semiconductor body deeper than the device isolation region, forming a collector region in the device region, forming a base region in the device region above the collector region, forming an emitter on the base region, and forming an insulating layer on the semiconductor body. The insulating layer is photo-etched to simultaneously form an emitter contact opening, a base contact opening and a collector contact opening, so that the emitter and base contact opening respectively extend to the emitter and the base region, and the collector contact opening extends through boundary portions of the deep-trench isolation region and the device isolation region to a point where the collector contact opening adjoins the corrector region.

### BRIEF DESCRIPTION OF THE DRAWINGS

The present invention will be described in detail further with reference to the following drawings, in which:

FIG. 1 is a top plan view of a pair of bipolar transistors constructed according to a first embodiment of the present invention;

FIG. 2 is a vertical cross-sectional view taken along the line 2-2 of FIG. 1;

FIGS. 3A to 3G are cross-sectional views for illustrating a process of fabricating the bipolar transistors of the first embodiment of the present invention;

FIG. 4 is a cross-sectional view of the first embodiment for comparison with the prior art bipolar transistors;

FIG. 5 is a cross-sectional view of an alternative form of the first embodiment of the present invention;

FIG. 6 is a cross-sectional view of a pair of double-polysilicon self-aligned bipolar transistors according to a second embodiment of the present invention;

FIGS. 7A to 7F are cross-sectional views for illustrating a process of fabricating the double-polysilicon self-aligned bipolar transistors; and

FIG. 8 is a top plan view of bipolar transistors illustrating modified configuration of collector trench contacts.

### DETAILED DESCRIPTION

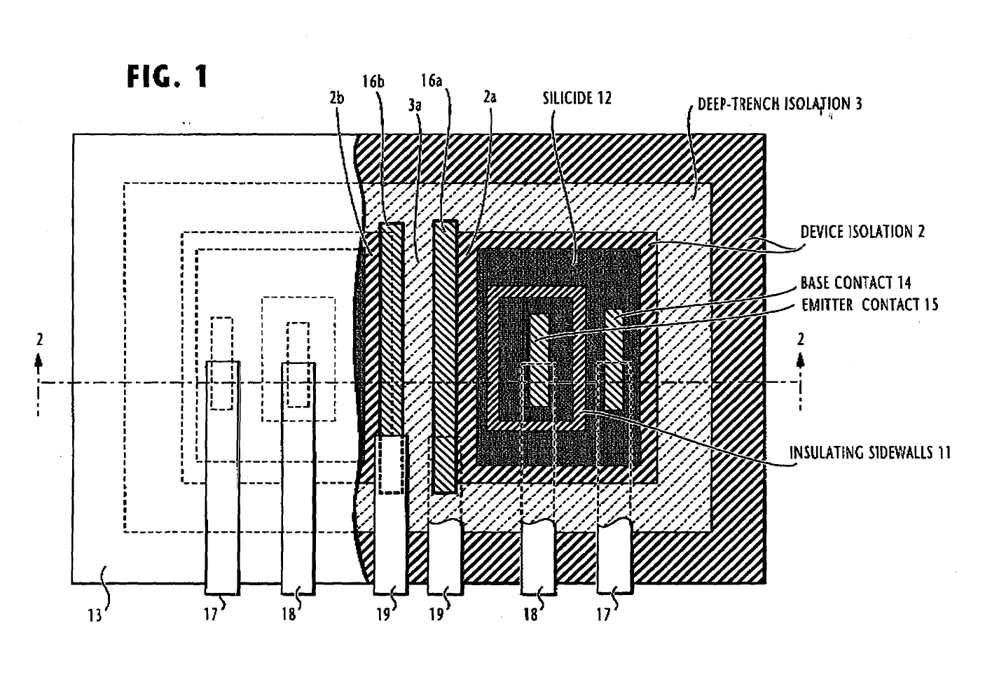

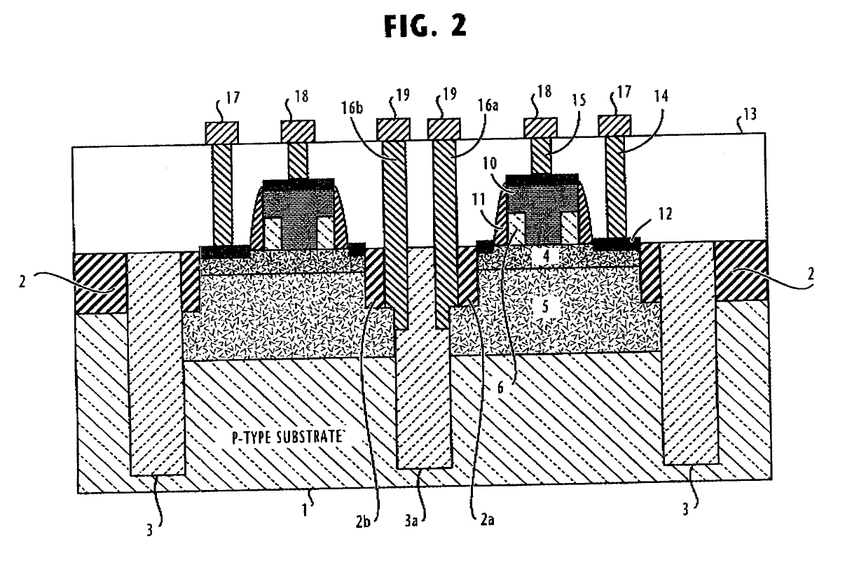

Referring now to FIGS. 1 and 2, there is shown an integrated circuit of bipolar transistors according to a first embodiment of the present invention is illustrated. A pair of bipolar transistors is integrated on a p-type silicon substrate 1. One photoetching process is used to form a deep-trench isolation region 3. Deep trench 3 extends vertically through a device isolation region 2 to a point near the bottom of the substrate and encloses the bipolar transistors and isolates them from each other. The center portion of isolation trench 3 serves not only as an isolation wall between the devices but also as a space for accommodating their collector contacts 16a, 16b. This structure eliminates the need to form a diffusion layer which would have been required for the prior art collector trench, while allowing collector contacts to directly contact a region 300 to 600 nanometers deep from the surface of the substrate 1 where the phosphorus concentration of the n-type well is highest. As a result, the space occupied by the bipolar transistors is reduced and hence their collector resistance R_{c} and collector-substrate capacitance C_{sub} are decreased using only one photoetching process.

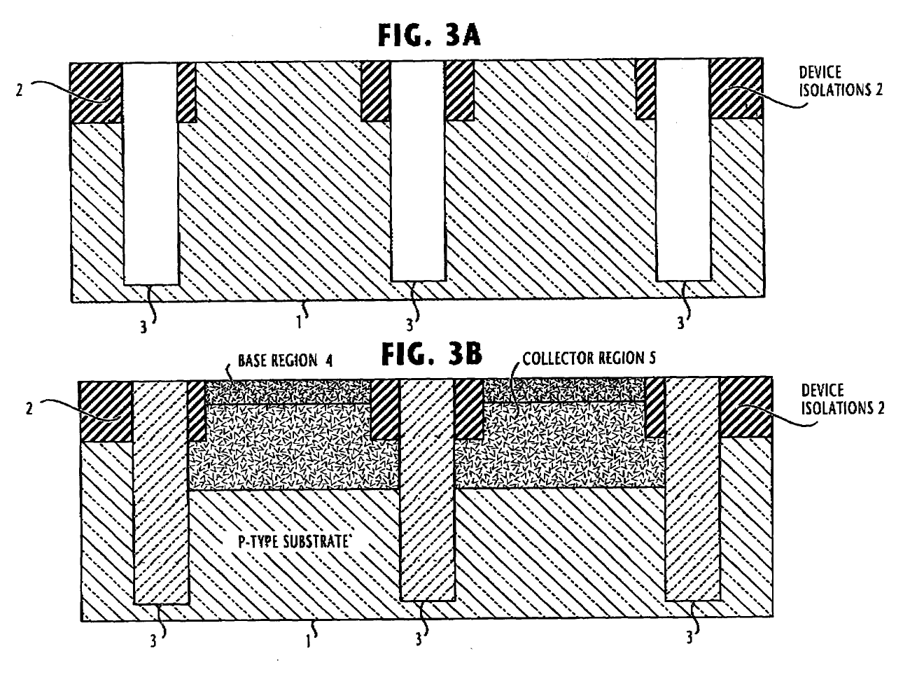

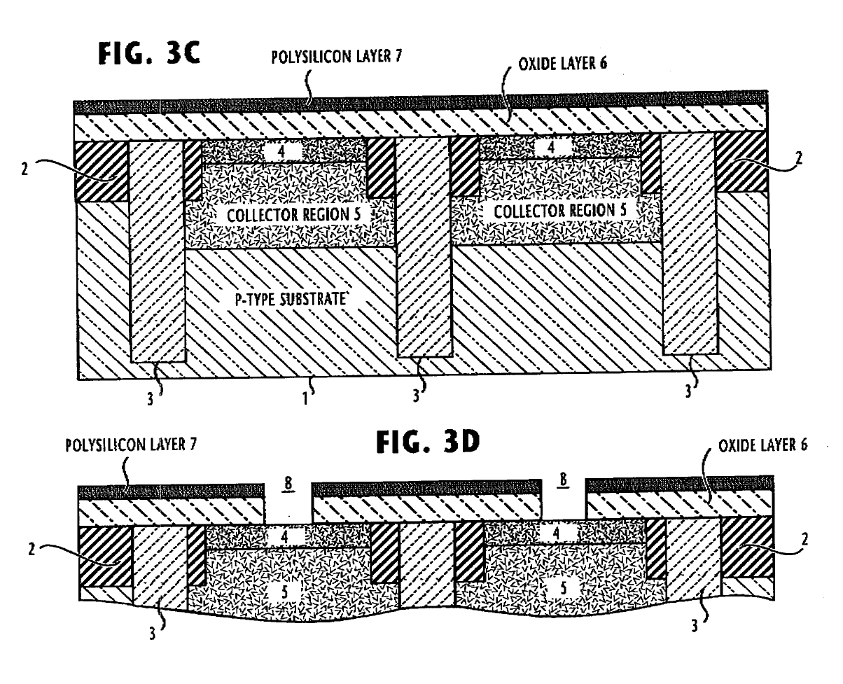

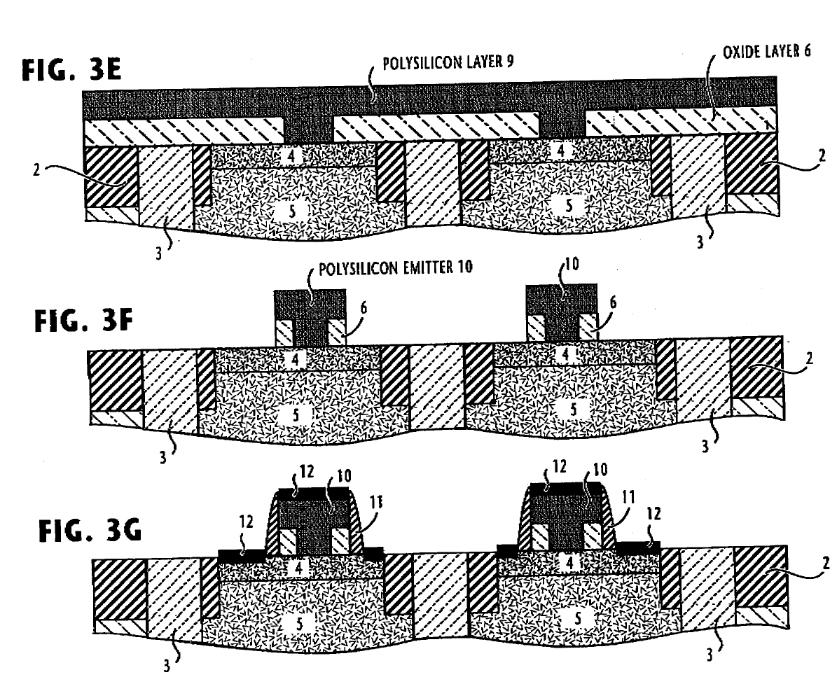

The integrated circuit of the bipolar transistors is fabricated in a manner as will be described below with reference to FIGS. 3A to 3G.

In FIG. 3A, a device isolation oxide layer 2 is formed on the surface of the substrate 1 and a deep trench 3 is etched through the device isolation region 2 to a depth of 300 to 600 nanometers near the bottom of the substrate. Deep trench 3 encloses areas where impurities will be diffused,

In FIG. 3B, the deep trench 3 is filled with oxides, and then ions are injected through a photomask, not shown, to form n-type collector regions 5 and p-type base regions 4.

After annealing the collector region 5 by performing an RTA (rapid thermal annealing) process at an elevated temperature of 1000°C. for a period of 30 seconds, an oxide layer 6 and a polysilicon layer 7 are successively deposited over the surface of the substrate (see FIG. 3C). Polysilicon layer 7 has the effect of protecting the oxide layer 6 from etching solution such as hydrofluoric acid which will be used before emitter polysilicon is grown. Using a photoresist mask, the oxide layer 6 and polysilicon layer 7 are dry-etched to form emitter windows 8 (FIG. 3D).

Next, SIC (selectively ion implanted collector) zones are formed to suppress the base push-out or Kirk effect which limits collector current density. The surface of the substrate is then rinsed with dilute hydrofluoric acid. On the rinsed surface is grown a layer 9 of polysilicon doped with phosphorus or arsenic with a concentration of 1E20˜3E20 cm⁻³, filling the emitter windows 8 (FIG. 3E).

Using a photoresist mask, the polysilicon layer 9 is dry-etched to form polysilicon emitters 10. The vertical profile of each polysilicon emitter 10 has a shape of the letter T with its stem corresponding in horizontal dimension to the emitter window and surrounded with a portion of the oxide layer 6 which is left unetched (FIG. 3F).

As shown in FIG. 3G, insulating sidewalls 11 are formed around the polysilicon emitters 10. Using a silicide forming technique, the upper surfaces of the polysilicon emitters 10 and the base region 4 are coated with silicide layers 12 to reduce their resistivity.

The semiconductor substrate is then coated with an insulation layer 13 to a thickness of 700 to 1300 nanometers from its upper surface and polished to a flat plane by using a CMP (chemical mechanical polishing) as shown in FIG. 2.

Using a photoresist mask, contact openings are etched through the insulation layer 13 to the polysilicon emitters, the base regions and collector regions. Etching is continued for the contact openings of collector regions 5 to form collector trenches that extend through adjoining boundary portions 2a and 3a of device isolation region 2 and deep-trench isolation region 3 and through adjoining boundary portions 2b and 3b. All contact openings are then filled with tungsten to form base contacts 14, emitter contacts 15 and collector trench contacts 16a, 16b (see FIGS. 1 and 2). Electrodes 17, 18 and 19 are respectively formed by a metallization process over the base contacts 14, emitter contacts 15 and collector contacts 16.

Since each collector trench is formed on the border line of the two isolation regions 2 and 3, the collector contact 16a is situated partly in the device isolation region 2a and partly in the deep-trench isolation region 3a. Likewise, the collector contact 16b is situated partly in the device isolation region 2b and partly in the deep-trench isolation region 3b. The lower end portion of each collector contact 16 that is etched through the deep-trench region 3a extends deeper than the other portion that is etched through the device isolation region 2a (2b) and runs along one edge of the associated rectangular-shaped collector region 5 as seen from FIGS. 1 and 2 to provide a sufficient area of ohmic contact.

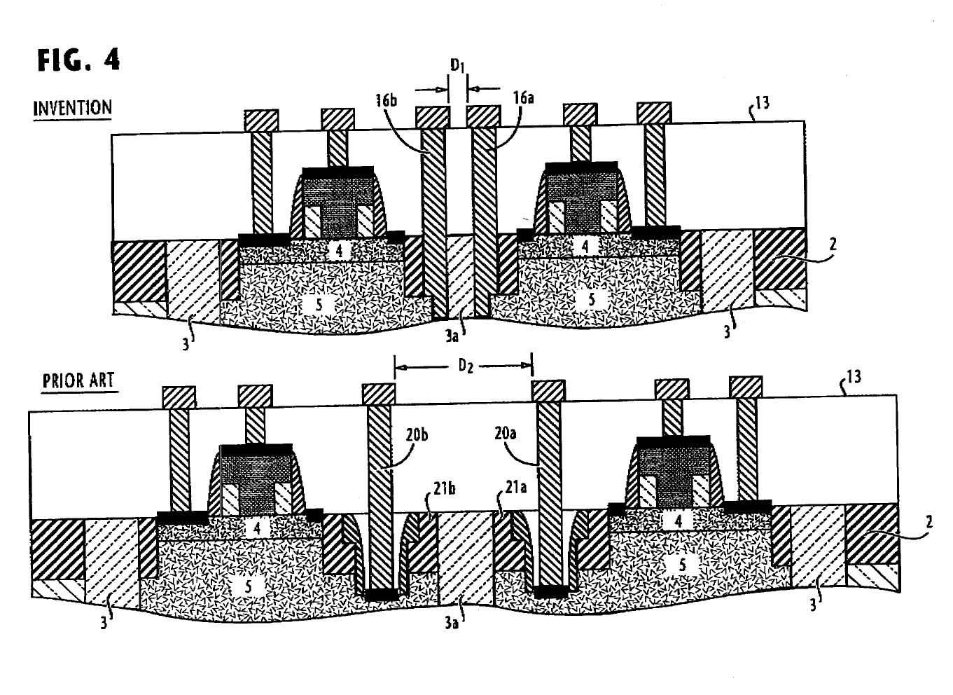

As shown in FIG. 4, the present invention compares favorably with the prior art integrated-circuit bipolar transistors. With the prior art, the collector regions 5 of adjacent bipolar transistors extend laterally toward each other in order to create collector contacts 20a, 20b in the device isolation regions 21a and 21b. On the other hand, the present invention utilizes the adjoining portions of the device isolation region 2 and deep-trench isolation region 3 to create the collector contacts 16a, 16b, Therefore, the collector electrode spacing D1 between adjacent bipolar transistors of the present invention is much smaller than the collector electrode spacing D2 of the prior art. Since the spacing D1 represents the spacing between adjacent bipolar transistors and since this spacing can be reduced to the minimum pitch of metallization, the cell area can be significantly reduced. Due to the reduced area of collector regions 5, the collector-substrate capacitance C_{sub} of the present invention is advantageously lower than that of the prior art.

Additionally, because of the border-line arrangement of the collector trenches, the spacing between each collector trench and the base region 4 can be reduced to the misalignment margin of a single photoetching process. This advantageously reduces the collector resistance R_{c}.

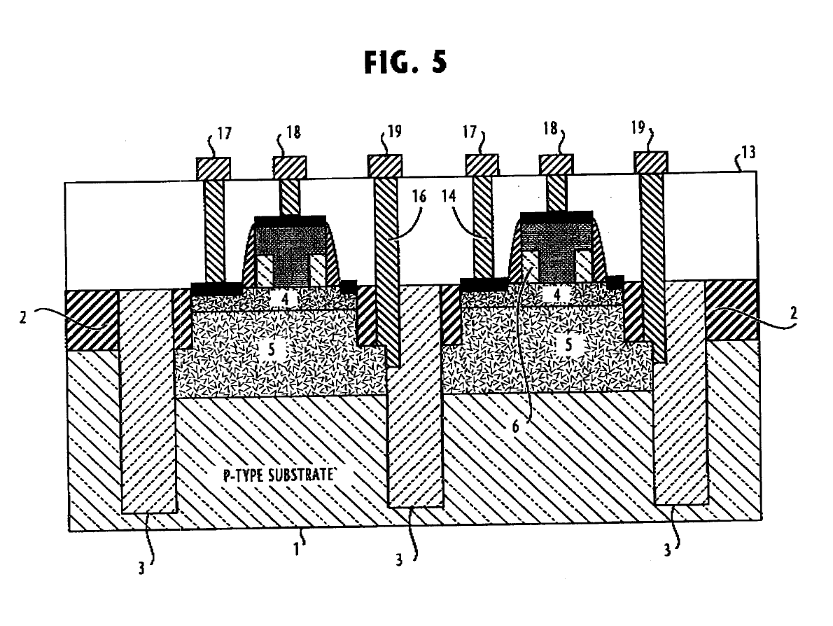

The bipolar transistors of the first embodiment of the present invention are symmetrically configured with respect to the center portion 3a of deep-trench isolation region 3. Alternatively, the bipolar transistors may be configured so that the collector contact 16 of one bipolar transistor is adjacent to the base contact 14 of the other transistor as shown in FIG. 5.

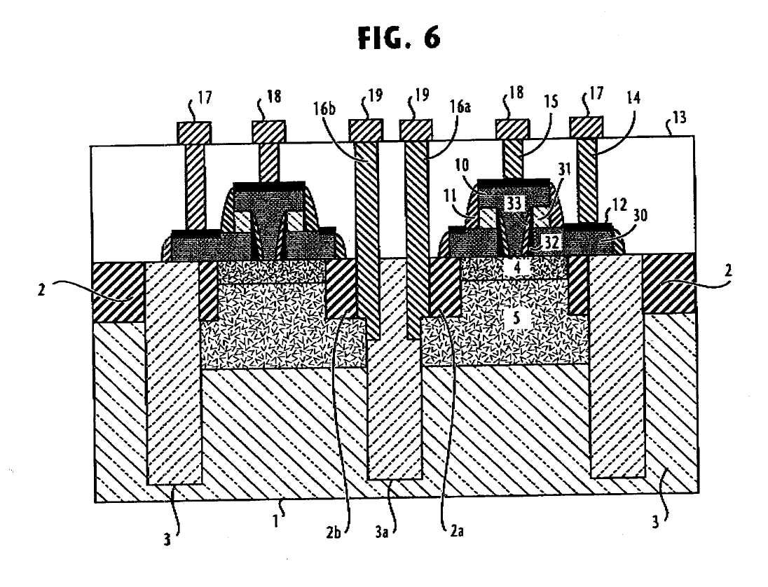

A second embodiment of the present invention is shown in FIG. 6 in which the present invention is incorporated in a double-polysilicon self-aligned structure. This structure differs from the first embodiment in that each bipolar transistor additionally comprises a polysilicon base region 30 and a nitride region 31 on the base region, which are isolated from the emitter 10 by oxide and nitride sidewalls 32 and 33.

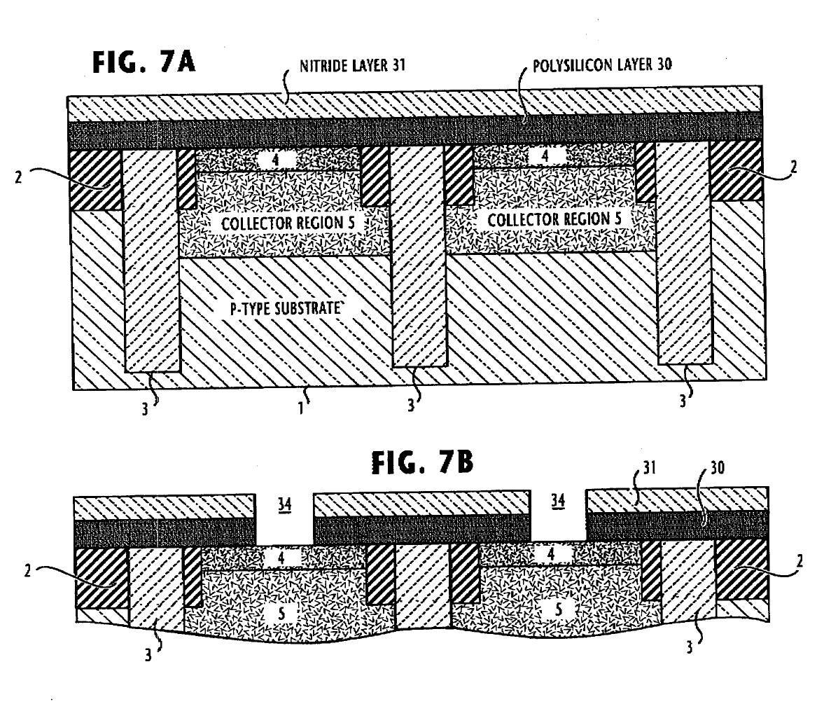

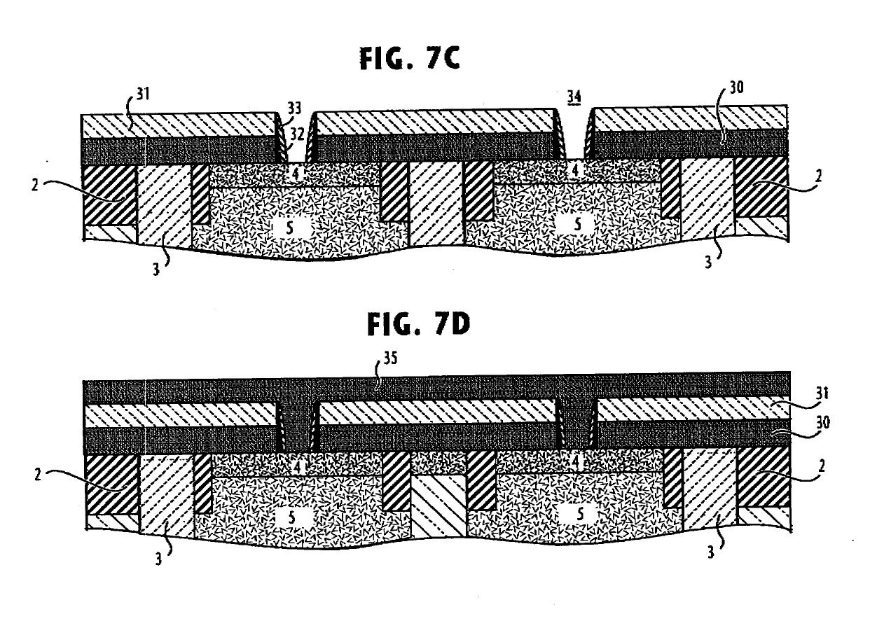

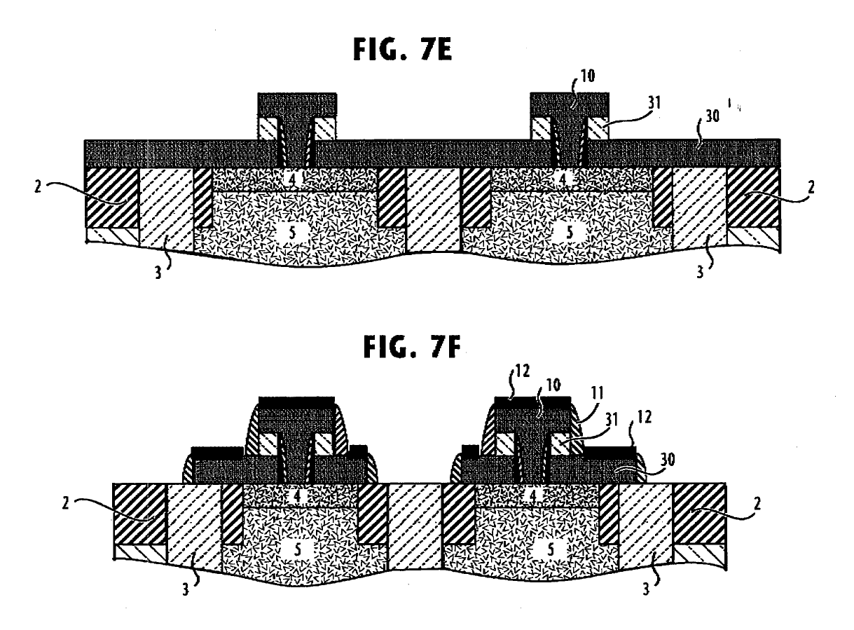

The double-polysilicon self-aligned integrated bipolar transistors are fabricated as shown in FIGS. 7A to 7F. The initial process is identical to that shown in FIGS. 3A and 3B. Therefore, the process begins with the structure of FIG. 3B. In FIG. 7A a p-type polysilicon layer 30 and a nitride layer 31 are successively formed on a structure identical to that shown in FIG. 3B. Each of these layers has a thickness in the range between 100 and 200 nanometers. Using a photoresist mask, emitter windows 34 are dry-etched through the layers 30 and 31 (FIG. 7B). Next, SIC zones are formed to suppress the Kirk effect. On the inner walls of each emitter window 34, an oxide sidewall 32 and a nitride sidewall 33 are formed (FIG. 7C). On the surface of the structure is grown a layer 35 of polysilicon doped with phosphorus or arsenic with a concentration of 1E20˜3E20 cm^{31 3}, filling the emitter windows 34 (FIG. 7D).

Using a photoresist mask, the polysilicon layer 35 and the nitride layer 31 are etched to form polysilicon emitters 10 of a generally T-shaped cross-section, leaving portions of the nitride layer 31 to remain around the stem of the T (FIG. 7E).

Similar to the previous embodiment, insulating sidewalls 11 are formed around the polysilicon emitters 10. Using a silicide forming technique, the upper surfaces of the polysilicon emitters 10 and the polysilicon bases 30 are coated with silicide layers 12 to reduce their resistivity (FIG. 7F). The semiconductor substrate is then coated with an insulation layer 13 to a thickness of 700 to 1300 nanometers from its upper surface and polished to a flat plane by using a CMP as shown in FIG. 6. Contacts 14, 15, 16a, 16b and corresponding electrodes 17, 18, 19 are successively formed in the same manner as described above.

Since the collector contacts 16a, 16b of the double-polysilicon self-aligned bipolar transistors are formed with no use of insulating sidewalls, space savings can be achieved with no risk of contaminating the etching process which would be performed to etch the laminated nitride and polysilicon layers to form polysilicon emitters.

The symmetrical arrangement of FIG. 6 may be modified in a manner similar to that shown in FIG. 5,

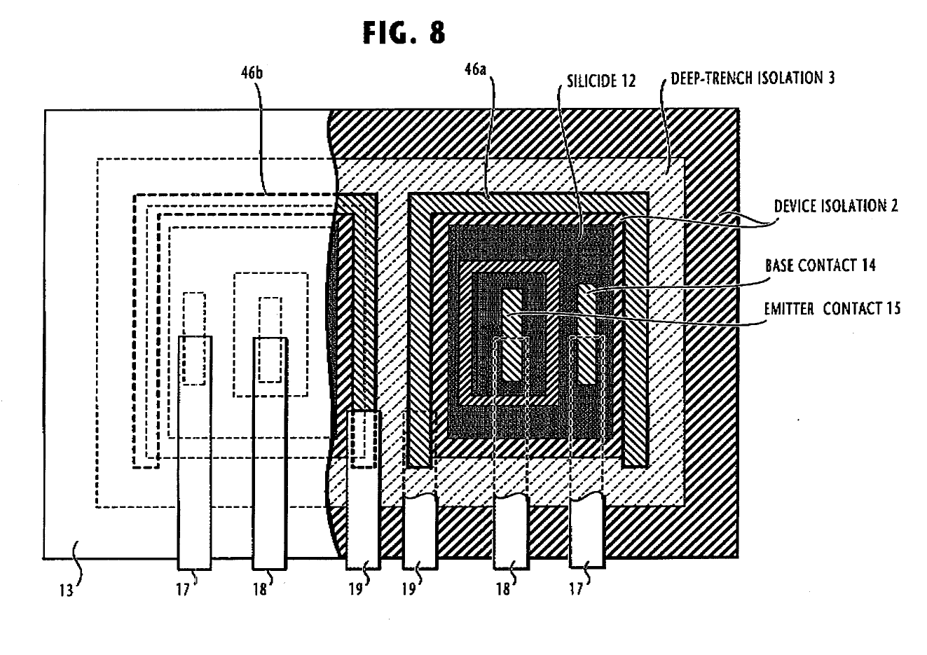

The collector resistance R_{c} of bipolar transistors can be further decreased with an arrangement of FIG. 8 in which collector trench contacts 46a, 46b are each formed in the shape of the letter of inverted U. Collector trench contacts 46a, 46b may take any desired shape according to the arrangement of collector electrodes 19. The shape of the letter L or the shape of a ring can also be used. If the ring-shape is used, emitter and base electrodes may be formed on a raised position with respect to the ring-shaped collector trench contact.

What is claimed is:

1. A bipolar transistor comprising:
a patterned deep-trench isolation region formed in a device isolation region which surrounds a device region of a semiconductor body, the deep-trench isolation region being embedded into the semiconductor body deeper than the device isolation region;
a base formed in the device region;
an emitter situated on the base; and
a collector comprising a collector region which forms a collector-base junction with the base and a collector trench contact embedded into boundary portions of the deep-trench isolation region and the device isolation region deeper than the device isolation region to establish an electrical contact with the corrector region.

2. The bipolar transistor of claim 1, wherein the emitter is composed of polysilicon.

3. The bipolar transistor of claim 2, wherein the emitter has a vertical cross-section with a shape of the letter T and the stem of the T is surrounded by oxide.

4. The bipolar transistor of claim 1, wherein the base comprises a lower layer of polysilicon and the emitter comprises of an upper layer of polysilicon on said lower layer.

5. The bipolar transistor of claim 4, wherein the emitter has a vertical cross-section with a shape of the letter T and the stem of the T is surrounded by a nitride region.

6. The bipolar transistor of claim 1, wherein the main collector region is in the shape of a rectangle and the collector trench contact extends along at least one edge of the rectangle of the main collector region.

7. A semiconductor device comprising:
a patterned device isolation region surrounding first and second device regions of a semiconductor body, the device isolation region being embedded in the semiconductor body along its upper surface;
a patterned deep-trench isolation region formed in the device isolation region, the deep-trench isolation region being embedded into the semiconductor body deeper than the device isolation region;
first and second bipolar transistors respectively formed in said first and second device regions, each of the first and second bipolar transistors comprising:
a base;
an emitter situated on the base; and
a collector comprising a collector region which forms a collector-base junction with the base and a collector trench contact embedded into boundary portions of the deeptrench isolation region and the device isolation region deeper than the device isolation region to establish an electrical contact with the corrector region,
the first and second bipolar transistors being symmetrically arranged with respect to a border line therebetween so that the collector trench contacts of the first and second bipolar transistors are adjacent to each other.

8. A semiconductor device comprising:
a patterned device isolation region surrounding first and second device regions of a semiconductor body, the device isolation region being embedded in the semiconductor body along its upper surface;
a patterned deep-trench isolation region formed in the device isolation region, the deep-trench isolation region-being embedded into the semiconductor body deeper than the device isolation region;
first and second bipolar transistors respectively formed in said first and second device regions, each of the first and second bipolar transistors comprising:
a base;
an emitter situated on the base; and
a collector comprising a collector region which forms a collector-base junction with the base and a collector trench contact embedded into boundary portions of the deep-trench isolation region and the device isolation region deeper than the device isolation region to establish an electrical contact with the corrector region,
the first and second bipolar transistors being arranged identically to each other so that the collector trench contacts of the first and second bipolar transistors are remote from each other.

9. The semiconductor device of claim 7 or 8, wherein of the emitter of each bipolar transistor is composed of polysilicon.

10. The semiconductor device of claim 9, wherein of the emitter of each bipolar transistor has a vertical cross-section with a shape of the letter T and the stem of the T is surrounded by an oxide region.

11. The semiconductor device of claim 7 or 8, wherein the base of each bipolar transistor comprises a lower layer of polysilicon and the emitter comprises of an upper layer of polysilicon on said lower layer.

12. The semiconductor device of claim 11, wherein the emitter of each bipolar transistor has a vertical cross-section with a shape of the letter T and the stem of the T is surrounded by a nitride region.

13. The semiconductor device of claim 7 or 8, wherein the main collector region of each bipolar transistor is in the shape of a rectangle and the collector trench contact of each bipolar transistor extends along at least one edge of the rectangle of the associated main collector region.

14. A method of fabricating a bipolar transistor, comprising:
forming a patterned deep-trench isolation region in a device isolation region which surrounds a device region of a semiconductor body deeper than the device isolation region;
forming a collector region in the device region;
forming a base region in the device region above the collector region;
forming an emitter on the base region;
forming an insulating layer on the semiconductor body; and
photoetching the insulating layer to simultaneously form an emitter contact opening, a base contact opening and a collector contact opening, so that the emitter and base contact opening respectively extend to said emitter and said base region, and the collector contact opening extends through boundary portions of the deep-trench isolation region and the device isolation region to a point where the collector contact opening adjoins the corrector region.

15. The method of claim 14, wherein the emitter is formed by:
depositing a layer of oxide on the semiconductor layer;
forming a window through the oxide layer to expose a portion of the base region to the outside;
depositing a layer of polysilicon on the oxide layer so that said window is filled with polysilicon;
photoetching the oxide and polysilicon layers to form a polysilicon emitter;
forming insulating sidewalls around the polysilicon emitter; and
depositing a silicide layer on the polysilicon emitter and an exposed area of the base region.

16. The method of claim 14, wherein the emitter is formed by:
depositing a first layer of polysilicon on the semiconductor layer;
depositing a layer of nitride on the first layer of polysilicon;
forming a window through the layers of polysilicon and nitride to expose a portion of the base region to the outside;
forming insulating sidewalls on inner walls of said window;
depositing a second layer of polysilicon on the nitride layer so that said window is filled with polysilicon;
photoetching the second polysilicon layer and the nitride layer to form a polysilicon emitter;
forming insulating sidewalls around the polysilicon emitter;
photoetching the first polysilicon layer to form a polysilicon base; and
depositing a silicide layer on the polysilicon emitter and an exposed area of the polysilicon base.
